(19) United States
(12) Patent Application Publication
(10) Pub. No.: US 2025/0006858 A1
(43) Pub. Date: Jan. 2, 2025

(54) DISPLAY PANEL AND MANUFACTURING METHOD THEREOF

(71) Applicants: XIAMEN UNIVERSITY, Xiamen, Fujian (CN); TAN KAH KEE INNOVATION LABORATORY, Xiamen, Fujian (CN)

(72) Inventors: Kai HUANG, Xiamen (CN); Xiaowei ZHANG, Xiamen (CN); Xu YANG, Xiamen (CN); Jinchai LI, Xiamen (CN); Rong ZHANG, Xiamen (CN)

(73) Assignees: XIAMEN UNIVERSITY, Xiamen, Fujian (CN); TAN KAH KEE INNOVATION LABORATORY, Xiamen, Fujian (CN)

(21) Appl. No.: 18/700,662

(22) PCT Filed: Apr. 19, 2023
(86) PCT No.: PCT/CN2023/089251

§ 371 Date: Apr. 11, 2024

(30) Foreign Application Priority Data
Aug. 29, 2022 (CN) 202211043484.9

(51) Int. Cl. H01L 33/00; H01L 25/075; H01L 33/62

(52) U.S. Cl. CPC H01L 33/005; H01L 25/0753; H01L 33/62; H01L 2933/0066

(57) ABSTRACT

The present application provides a display panel and a manufacturing method thereof, the manufacturing method comprises: providing a first substrate, wherein a side of the first substrate is provided with a plurality of Micro-LED chips that are spaced apart from each other; providing a second substrate, wherein a surface on a side of the second substrate has a plurality of conductive layer parts; forming an isolation layer on the second substrate, wherein the isolation layer has a plurality of opening groups, each of the opening groups comprises a first opening and a second opening to expose a surface of one of the conductive layer parts, wherein a width of the first opening is greater than that of a P-type electrode, and a width of the second opening is greater than that of a N-type electrode; forming a first bonding layer in the first opening and forming a second bonding layer in the second opening; while supporting the chip body by the isolation layer, bonding the P-type electrode with the first bonding layer and simultaneously bonding the N-type electrode with the second bonding layer, wherein the P-type electrode is embedded into the first bonding layer and the N-type electrode is embedded into the second bonding layer.

### CROSS-REFERENCE TO RELATED APPLICATION

The present application claims the priority of Chinese patent application No. 202211043484.9, filed to the CNIPA on Aug. 29, 2022, and entitled “Display Panel and Manufacturing Method Thereof”, which is incorporated herein by reference in its entirety.

### TECHNICAL FIELD

The present application relates to the technical field of display, particularly relates to a display panel and a manufacturing method thereof.

### BACKGROUND

Light-Emitting Diode (LED) is a kind of important photoelectric semiconductor element. Light-Emitting Diodes (LEDs) are widely used as light sources because of their advantages of low power consumption, small size, high brightness, easy matching with integrated circuits, and high reliability. With development of technology, Micro-LED has been applied in fields of display, optical communication, indoor locating, and biology and medical treatment, and is expected to be further extended to wearable/implantable devices, augmented reality/virtual reality, vehicle on-board display, super-large display, optical communication/optical interconnection, medical detection, intelligent car lights, space imaging, and other fields, which has a clear and considerable market prospect. When Micro-LED chips are applied to display technology, millions or even tens of millions of Micro-LED chips need to be transferred to a display panel accurately and efficiently. Taking a 4K TV as an example, the number of Micro-LED chips to be transferred is as high as 24 million (calculated by 4000×2000×R/G/B three-primary colors), and even if 10,000 Micro-LED chips are transferred at one time, it needs to be repeated 2,400 times.

However, accuracy of a bonding position between a Micro-LED chip and a substrate is poor in the prior art, resulting in bonding failure between the Micro-LED chip and the bonding layer.

### SUMMARY

Therefore, a technical problem to be solved by the present application is to overcome the problem of bonding failure between a Micro-LED chip and a bonding layer in the prior art, thereby providing a display panel and a manufacturing method thereof.

The present application provides a manufacturing method for a display panel, comprising: providing a first substrate, wherein a side of the first substrate is provided with a plurality of Micro-LED chips that are spaced apart from each other, wherein each of the Micro-LED chips comprises: a chip body; a P-type electrode and a N-type electrode, which are arranged on part of a surface on a side of the chip body; providing a second substrate, wherein a surface on a side of the second substrate has a plurality of conductive layer parts; forming an isolation layer on the second substrate, wherein the isolation layer has a plurality of opening groups, each of the opening groups comprises a first opening and a second opening that are spaced apart from each other, wherein the first opening and the second opening respectively expose a surface of one of the conductive layer parts, and a width of the first opening is greater than a width of the P-type electrode, and a width of the second opening is greater than a width of the N-type electrode; forming a first bonding layer in the first opening and forming a second bonding layer in the second opening; while supporting the chip body by the isolation layer, bonding the P-type electrode with the first bonding layer and simultaneously bonding the N-type electrode with the second bonding layer, wherein the P-type electrode is embedded into the first bonding layer and the N-type electrode is embedded into the second bonding layer.

Optionally, the chip body comprises: a N-type semiconductor layer; an active layer, positioned on part of a surface on a side of the N-type semiconductor layer; a P-type semiconductor layer, positioned on a surface on a side, away from the N-type semiconductor layer, of the active layer; the P-type electrode is positioned on part of a surface on a side, away from the active layer, of the P-type semiconductor layer; the N-type electrode is positioned on part of the surface on the side of the N-type semiconductor and arranged laterally beside the active layer, the P-type semiconductor layer and the P-type electrode; in a process of bonding the P-type electrode with the first bonding layer and simultaneously bonding the N-type electrode with the second bonding layer, a portion of the P-type semiconductor layer around the P-type electrode is supported by the isolation layer.

Optionally, the method further comprises: before the step of forming the first bonding layer in the first opening, forming a first slope surface at a junction between a sidewall of the first opening and a top surface of the isolation layer around the first opening; before the step of forming the second bonding layer in the second opening, forming a second slope surface at a junction between a sidewall of the second opening and a top surface of the isolation layer around the second opening.

Optionally, a first included angle is formed between the first slope surface and the top surface of the isolation layer connected to the first slope surface; wherein tan (180°−θ1)>μ1, wherein θ1 is the first included angle, and μ1 is a friction coefficient of the first slope surface.

Optionally, a second included angle is formed between the second slope surface and the top surface of the isolation layer connected to the second slope surface; wherein tan (180°−θ2)>μ2, wherein θ2 is the second included angle, and μ2 is a friction coefficient of the second slope surface.

Optionally, the method further comprises: before the step of bonding the P-type electrode with the first bonding layer and simultaneously bonding the N-type electrode with the second bonding layer, forming a barrier layer upon the isolation layer around the opening groups, wherein the barrier layer has third openings, and a width of each of the third openings is greater than a width of each of the Micro-LED chips.

Optionally, the width of each of the third openings is less than or equal to 1.5 times of the width of each of the Micro-LED chips.

Optionally, the barrier layer is a light-shielding barrier layer.

Optionally, a material of the light-shielding barrier layer is light-shielding resin.

Optionally, after the step of bonding the P-type electrode with the first bonding layer and simultaneously bonding the N-type electrode with the second bonding layer, a height of a top surface of a side, away from the second substrate, of the barrier layer is greater than a height of a top surface of a side, away from the second substrate, of each of the Micro-LED chips.

Optionally, in a process of bonding the P-type electrode with the first bonding layer and simultaneously bonding the N-type electrode with the second bonding layer, a binding equipment that is used has an error within feature alignment accuracy; the width of the first opening is greater than or equal to a sum of the width of the P-type electrode and 2 times of the error within feature alignment accuracy, and the width of the second opening is greater than or equal to a sum of the width of the N-type electrode and 2 times of the error within feature alignment accuracy.

Optionally, in the step of forming a first bonding layer in the first opening and a second bonding layer in the second opening, the thickness of the first bonding layer is greater than or equal to 80% of the depth of the first opening and less than or equal to the depth of the first opening, and the thickness of the second bonding layer is greater than or equal to 80% of the depth of the second opening and less than or equal to the depth of the second opening.

Optionally, a thickness of the isolation layer is less than or equal to 50% of a thickness difference between the N-type electrode and the P-type electrode.

Optionally, the thickness of the isolation layer is 500 nm˜1000 nm.

Optionally, a material of the first bonding layer and the second bonding layer is solder; or a material of the first bonding layer and the second bonding layer is conductive adhesive.

The present application further provides a display panel comprising: a first substrate, wherein a side of the first substrate is provided with a plurality of Micro-LED chips that are spaced apart from each other, and each of the Micro-LED chips comprises: a chip body; a P-type electrode and a N-type electrode, which are arranged on part of a surface on a side of the chip body; a second substrate, wherein a surface on a side of the second substrate has a plurality of conductive layer parts; an isolation layer, positioned on the side of the second substrate, wherein the isolation layer has a plurality of opening groups, each of the opening groups comprises a first opening and a second opening that are spaced apart from each other, the first opening and the second opening are respectively positioned over one of the conductive layer parts, a width of the first opening is greater than a width of the P-type electrode, and a width of the second opening is greater than a width of the N-type electrode; a first bonding layer, positioned in the first opening; a second bonding layer, positioned in the second opening; wherein the P-type electrode is embedded in the first bonding layer, and the N-type electrode is embedded in the second bonding layer; the chip body touches part of a top surface of the isolation layer.

Optionally, the chip body comprises: a N-type semiconductor layer; an active layer, positioned on part of a surface on a side of the N-type semiconductor layer; a P-type semiconductor layer, positioned on a surface on a side, away from the N-type semiconductor layer, of the active layer; the P-type electrode is positioned on part of a surface on a side, away from the active layer, of the P-type semiconductor layer; the N-type electrode is positioned on part of the surface on the side of the N-type semiconductor and arranged laterally beside the active layer, the P-type semiconductor layer and the P-type electrode; a portion of the P-type semiconductor layer around the P-type electrode touches the top surface of the isolation layer around the first opening.

Optionally, a first slope surface is provided between a sidewall of the first opening and the top surface of the isolation layer around the first opening; a second slope surface is provided between a sidewall of the second opening and the top surface of the isolation layer around the second opening.

Optionally, a first included angle is formed between the first slope surface and the top surface of the isolation layer connected to the first slope surface; wherein tan (180°−θ1)>μ1,wherein θ1 is the first included angle, and μ1 is a friction coefficient of the first slope surface.

Optionally, a second included angle is formed between the second slope surface and the top surface of the isolation layer connected to the second slope surface; wherein tan (180°−θ2)>μ2, wherein θ2 is the second included angle, and μ2 is a friction coefficient of the second slope surface.

Optionally, the display panel further comprises: a barrier layer, positioned upon the isolation layer around the opening groups, wherein the barrier layer has third openings, and a width of each of the third openings is greater than a width of each of the Micro-LED chips.

Optionally, the width of each of the third openings is less than or equal to 1.5 times of the width of each of the Micro-LED chips.

Optionally, the barrier layer is a light-shielding barrier layer.

Optionally, a material of the light-shielding barrier layer is light-shielding resin.

Optionally, after bonding the P-type electrode with the first bonding layer and simultaneously bonding the N-type electrode with the second bonding layer, a height of a top surface of a side, away from the second substrate, of the barrier layer is greater than a height of a top surface of a side, away from the second substrate, of each of the Micro-LED chips.

Optionally, the width of the first opening is greater than or equal to a sum of the width of the P-type electrode and 2 times of an error within feature alignment accuracy, and the width of the second opening is greater than or equal to a sum of the width of the N-type electrode and 2 times of the error within feature alignment accuracy, wherein the error within the feature alignment accuracy is 0.5 μm˜2 μm.

Optionally, a thickness of the first bonding layer is greater than or equal to 80% of a depth of the first opening and less than or equal to the depth of the first opening, and a thickness of the second bonding layer is greater than or equal to 80% of a depth of the second opening and less than or equal to the depth of the second opening.

Optionally, a thickness of the isolation layer is less than or equal to 50% of a thickness difference between the N-type electrode and the P-type electrode.

Optionally, the thickness of the isolation layer is 500 nm˜1000 nm.

Optionally, a material of the first bonding layer and the second bonding layer is solder; or a material of the first bonding layer and the second bonding layer is conductive adhesive.

The technical solution of the present application has the following beneficial effects: In the manufacturing method for a display panel provided by the present application, while supporting the chip body by the isolation layer, bonding the P-type electrode with the first bonding layer and simultaneously bonding the N-type electrode with the second bonding layer, wherein the P-type electrode is embedded into the first bonding layer and the N-type electrode is embedded into the second bonding layer. The first opening allows the P-type electrode to enter and the second opening allows the N-type electrode to enter, while the isolation layer supports the chip body at a position around the P-type electrode, thereby adding a self-alignment function, and a lateral offset of the Micro-LED chip is limited by both a side wall of the first opening and a side wall of the second opening, thereby ensuring stability of bonding. Secondly, a material of the first bonding layer is confined within the first opening, and a material of the second bonding layer is confined within the second opening, so as to reduce a lateral deviation of both the material of the first bonding layer and the material of the second bonding layer during a bonding process and prevent a short circuit between the first bonding layer and the second bonding layer. In conclusion, a purpose of preventing failure of bonding between the Micro-LED chips and both the first bonding layer and the second bonding layer is served.

### BRIEF DESCRIPTION OF DRAWINGS

In order to explain more clearly technical solutions in specific embodiments of the present application or in the prior art, the drawings that need to be used in the description of specific embodiments or the prior art is briefly introduced below. It is apparent that the drawings described below only represent some embodiments of the present application, and other drawings may be obtained from these drawings without expenditure of any creative effort by a person skilled in the art.

FIG. 1 to FIG. 2 are schematic diagrams of a manufacturing process of a display panel;

FIG. 3 to FIG. 4 are schematic diagrams of another manufacturing process of a display panel;

FIG. 5 to FIG. 10 are schematic diagrams of a manufacturing process of a display panel provided by an embodiment of the present application;

FIG. 11 to FIG. 13 are schematic diagrams of a manufacturing process of a display panel provided by another embodiment of the present application;

FIG. 14 to FIG. 16 are schematic diagrams of a manufacturing process of a display panel provided by another embodiment of the present application.

### DETAILED DESCRIPTION OF EMBODIMENTS

As described in the background, accuracy of a bonding position between a Micro-LED chip and a substrate is poor in the prior art, resulting in bonding failure.

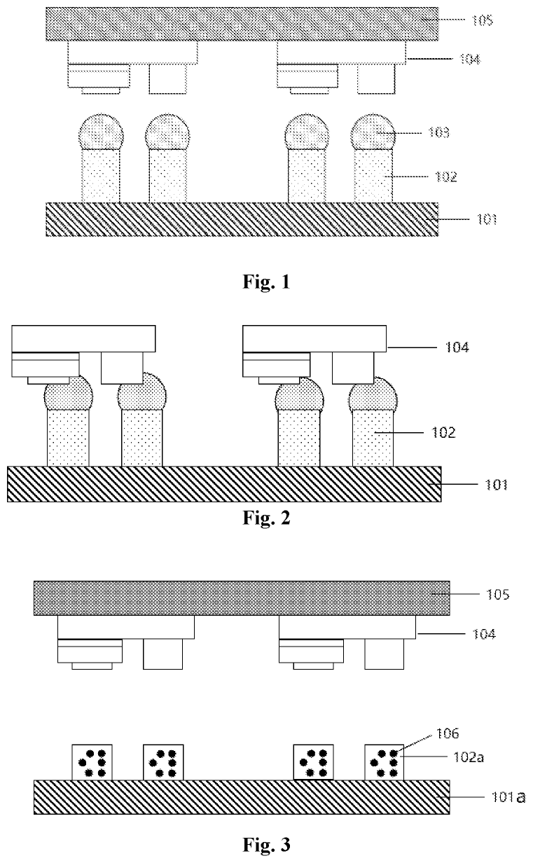

A manufacturing method for a display panel comprises: referring to FIG. 1, providing a first substrate 101 having a conductive post 102, wherein a surface, away from the first substrate 101, of the conductive post 102 is applied with solder 103; providing a second substrate 105, wherein a surface on a side of the second substrate 105 has a plurality of Micro-LED chips 104 spaced apart from each other; arranging the second substrate 105 and the first substrate 101 to face each other so that the plurality of Micro-LED chips 104 face the solder 103; referring to FIG. 2, soldering electrodes of the plurality of Micro-LED chips 104 and the solder 103.

However, in a process of soldering the electrodes of the plurality of Micro-LED chips 104 and the solder 103 together, the electrode of the Micro-LED chip 104 would deviate from the solder 103 to some degree, resulting in weak soldering or even short circuit. By studies, it is found to be due to: 1. during a process of alignment between the electrode of the Micro-LED chip 104 and the solder 103, it is subjected to limitation of alignment accuracy of an aligning equipment; 2. reflow-soldering is adopted to solder the electrode of the Micro-LED chip 104 and the solder 103, wherein the solder 103 would be melted during a process of the reflow-soldering, resulting in position deviation of the Micro-LED chip 104 from the solder 103; 3. a eutectic vacuum furnace used for soldering the electrode of the Micro-LED chip 104 and the solder 103 does not have a pressure system, and therefore a relative position between the Micro-LED chip 104 and the solder 103 cannot be maintained.

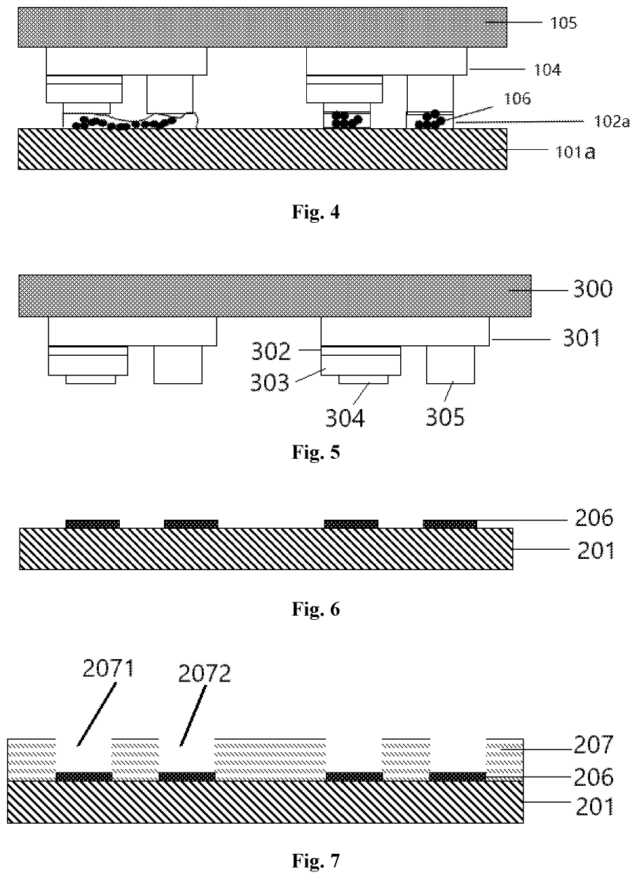

In another manufacturing method for a display panel, referring to FIG. 3, providing a first substrate 101a which has a surface provided with a plurality of electrodes (not shown), a surface of each of the plurality of electrodes has conductive adhesive 102a which has conductive particles 106 therein; referring to FIG. 3, providing a second substrate 105, wherein a surface on a side of the second substrate 105 has a plurality of Micro-LED chips 104 spaced apart from each other, wherein each of the plurality of Micro-LED chips 104 comprises a P-type electrode and a N-type electrode; referring to FIG. 4, arranging a second substrate 105 and a first substrate 101a to face each other, bonding the P-type electrode of each of the plurality of Micro-LED chips 104 and part of the conductive adhesive 102a together, and bonding the N-type electrode of each of the plurality of Micro-LED chips 104 and part of the conductive adhesive 102a together.

However, in a process of bonding the N-type electrode of each of the plurality of Micro-LED chips 104 and part of the conductive adhesive 102a together, when a distance between the N-type electrode and the P-type electrode is small, a short circuit between the N-type electrode and the P-type electrode would easily be caused.

In the aforesaid methods there are always high risks of bonding failure between the electrode of the Micro-LED chip 104 and the bonding layer (solder 103 or conductive adhesive 102a).

The present application provides a display panel and a manufacturing method thereof, which can prevent bonding failure between a Micro-LED chip and a bonding layer.

A clear and complete description of technical solutions of the present application is given below in conjunction with accompanying drawings and it is apparent that the described embodiments only represent a part of and not all of embodiments of the present application. Based on the embodiments described in the present application, all other embodiments obtainable by a person skilled in the art without making creative efforts fall within the protection scope of the present application.

In the description of the present application, it should be noted that the terms such as “center”, “up”, “down”, “left”, “right”, “vertical”, “horizontal”, “inside”, “outside”, etc. Denote orientations or positional relationships based on those shown in the drawings, are intended for ease of description and simplification of the description only, and are not intended to indicate or imply that the device or element in question must have a particular orientation or must be constructed and operated in a particular orientation, and therefore cannot be construed as a limitation to the present application. Furthermore, the terms such as “first”, “second” and “third” are used for descriptive purposes only and cannot be understood to indicate or imply relative importance.

In the description of the present application, it should be noted that, unless otherwise expressly specified and limited, the terms such as “mounted”, “connected” and “coupled” are understood in a broad sense, for example, it may be fixedly, detachably, or integrally connected; it may be mechanical connection or electrical connection; it may be directly connected or indirectly connected through an intermediate medium, or it may be internal communication between two components; it may be wireless or wired connection. For a person skilled in the art, the specific meanings of the above terms in the present application can be understood according to specific context thereof.

In addition, the technical features described below in various embodiments of the present application may be combined with each other as long as they do not conflict with each other.

### Embodiment 1

An embodiment of the present application provides a manufacturing method for a display panel, comprising:

S1: providing a first substrate, wherein a side of the first substrate is provided with a plurality of Micro-LED chips that are spaced apart from each other, wherein each of the Micro-LED chips comprises: a chip body; a P-type electrode and a N-type electrode, which are arranged on part of a surface on a side of the chip body;

S2: providing a second substrate, wherein a surface on a side of the second substrate has a plurality of conductive layer parts;

S3: forming an isolation layer on the second substrate, wherein the isolation layer has a plurality of opening groups, each of the opening groups comprises a first opening and a second opening that are spaced apart from each other, wherein the first opening and the second opening respectively expose a surface of one of the conductive layer parts, and a width of the first opening is greater than a width of the P-type electrode, and a width of the second opening is greater than a width of the N-type electrode;

S4: forming a first bonding layer in the first opening and forming a second bonding layer in the second opening;

S5: while supporting the chip body by the isolation layer, bonding the P-type electrode with the first bonding layer and simultaneously bonding the N-type electrode with the second bonding layer, wherein the P-type electrode is embedded into the first bonding layer and the N-type electrode is embedded into the second bonding layer.

In this embodiment, the first opening allows the P-type electrode to enter, and the second opening allows the N-type electrode to enter, while the isolation layer supports the chip body at a position around the P-type electrode, thereby adding a self-alignment function, and a lateral offset of the Micro-LED chip is limited by both a side wall of the first opening and a sidewall of the second opening, thus ensuring bonding stability. Secondly, a material of the first bonding layer is confined within the first opening, and a material of the second bonding layer is confined within the second opening, so as to reduce a lateral deviation of both the material of the first bonding layer and the material of the second bonding layer during a bonding process, thereby preventing a short circuit between the first bonding layer and the second bonding layer. In conclusion, a purpose of preventing failure of bonding between the Micro-LED chips and both the first bonding layer and the second bonding layer is served.

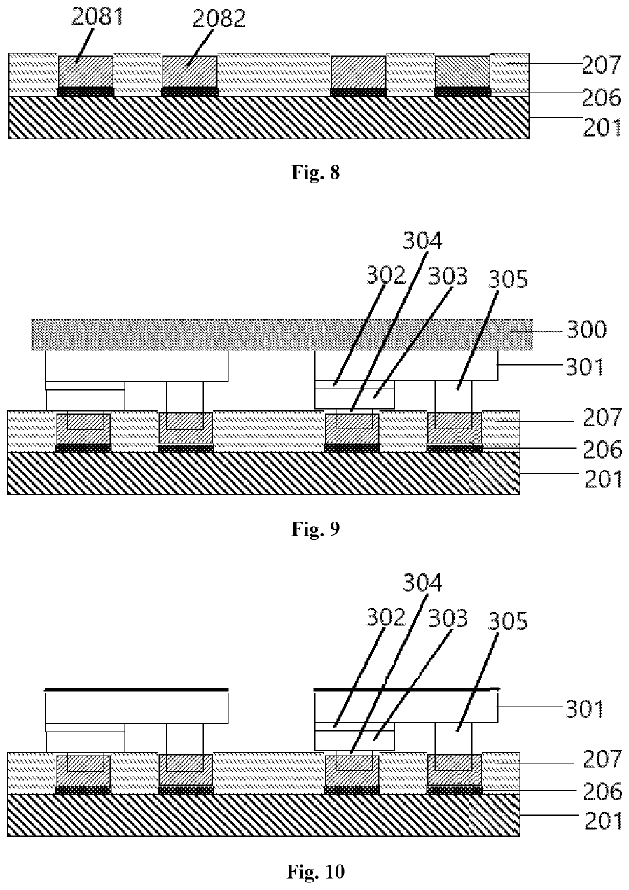

A detailed description is given below in conjunction with FIG. 5 to FIG. 10.

Referring to FIG. 5, providing a first substrate 300, wherein a side of the first substrate 300 is provided with a plurality of Micro-LED chips that are spaced apart from each other, wherein each of the Micro-LED chips comprises: a chip body; a P-type electrode 304 and a N-type electrode 305, which are arranged on part of a surface on a side of the chip body.

The chip body comprises: a N-type semiconductor layer 301; an active layer 302, positioned on part of a surface on a side of the N-type semiconductor layer 301; a P-type semiconductor layer 303, positioned on a surface on a side, away from the N-type semiconductor layer 301, of the active layer 302; the P-type electrode 304 is positioned on part of a surface on a side, away from the active layer 302, of the P-type semiconductor layer 303; the N-type electrode 305 is positioned on part of the surface on the side of the N-type semiconductor layer 301 and arranged laterally beside the active layer 302, the P-type semiconductor layer 303 and the P-type electrode 304.

In this embodiment, the P-type electrode 304 is positioned on part of a surface on a side, away from the active layer 302, of the P-type semiconductor layer 303, that is, part of the surface of the P-type semiconductor layer 303 is not covered by the P-type electrode 304.

In an embodiment, a difference between a total area of the surface on the side of the P-type semiconductor layer 303 facing away from the active layer 302 and a projected area of the P-type electrode 304 on the surface of the P-type semiconductor layer 303 is 50 μm²˜200 μm2, for example, 50 μm², 80 μm², 100 μm², 120 μm², 150 μm², 180 μm², or 200 μm².

In an embodiment, a distance between the N-type electrode 305 and the P-type electrode 304 in the Micro-LED chip is 5 microns˜6 microns.

Referring to FIG. 6, providing a second substrate 201, wherein a surface on a side of the second substrate 201 has a plurality of conductive layer parts 206.

The second substrate 201 is a driving substrate which comprises a substrate body and a driving circuit arranged on a surface on a side of the substrate body. The conductive layer 206 is arranged on a surface on a side of the driving circuit facing away from the substrate body, and the conductive layer 206 is electrically connected to the driving circuit.

The conductive layer 206 is a contact electrode and is formed by film formation, photolithography, and etching. A material of the conductive layer 206 comprises metal or alloy, and for example, the metal may be Al, Ti, or Mo.

Referring to FIG. 7, forming an isolation layer 207 on the second substrate 201, wherein the isolation layer 207 has a plurality of opening groups, each of the opening groups comprises a first opening 2071 and a second opening 2072 that are spaced apart from each other, wherein the first opening 2071 and the second opening 2072 respectively expose a surface of one of the conductive layer parts 206, and a width of the first opening 2071 is greater than a width of the P-type electrode 304, and a width of the second opening 2072 is greater than a width of the N-type electrode 305.

Steps for forming the isolation layer 207 comprises: forming an initial isolation layer (not shown in the drawings) covering the conductive layer parts 206 on the second substrate 201; patterning the initial isolation layer, so as to form the isolation layer 207 from the initial solation layer.

In an embodiment, a thickness of the isolation layer 207 is less than or equal to 50% of a thickness difference between the N-type electrode 305 and the P-type electrode 304. The thickness of the isolation layer 207 refers to a dimension along a direction perpendicular to the surface of the second substrate 201; the thickness of the N-type electrode 305 and the thickness of the P-type electrode 304 both refer to dimensions along a direction perpendicular to the surface of the first substrate. This arrangement has advantages that the thickness of the isolation layer 207 is relatively thin, thereby saving costs; meanwhile, better contact between the P-type electrode 304 and the material of a subsequently-formed first bonding layer and better contact between the N-type electrode 305 and the material of a subsequently-formed second bonding layer can both be ensured.

In a specific embodiment, the thickness of the isolation layer is 500 nm˜1000 nm.

The material of the isolation layer 207 comprises SiO₂ or Si₃N₄.

The width of each of the conductive layer parts 206 at the bottom of a first opening 2071 is greater than or equal to the width of the first opening 2071, and the width of each of the conductive layer parts 206 at the bottom of a second opening 2072 is greater than or equal to the width of the second opening 2072. The width of each of the conductive layer parts 206 arranged at the bottom of the first opening 2071 is greater than or equal to a sum of the width of the P-type electrode 304 and 2 times of an error within feature alignment accuracy, and the width of each of the conductive layer parts 206 arranged at the bottom of the second opening 2072 is greater than or equal to a sum of the width of the N-type electrode 305 and 2 times of the error within feature alignment accuracy. The feature alignment accuracy is an alignment accuracy of a binding equipment used in a subsequent process of bonding the P-type electrode 304 with the first bonding layer 2081 and simultaneously bonding the N-type electrode 305 with the second bonding layer 2082.

Referring to FIG. 8, forming a first bonding layer 2081 in the first opening 2071 and forming a second bonding layer 2082 in the second opening 2072.

In an embodiment, a material of the first bonding layer 2081 and the second bonding layer 2082 is solder which may comprise In solder or tin-containing solder without lead.

In another embodiment, a material of the first bonding layer 2081 and the second bonding layer 2082 is conductive adhesive which may be anisotropic conductive adhesive.

A melting point of the first bonding layer 2081 is lower than that of each of the conductive layer parts 206 and lower than that of the isolation layer 207. A melting point of the second bonding layer 2082 is lower than that of each of the conductive layer parts 206 and lower than that of the isolation layer 207.

In the step of forming a first bonding layer 2081 in the first opening 2071 and forming a second bonding layer 2082 in the second opening 2072, the thickness of the first bonding layer 2081 is greater than or equal to 80% of the depth of the first opening 2071 and less than or equal to the depth of the first opening 2071, and the thickness of the second bonding layer 2082 is greater than or equal to 80% of the depth of the second opening 2072 and less than or equal to the depth of the second opening 2072. This makes the material of the first bonding layer 2081 able to surround the P-type electrode and makes the material of the second bonding layer 2082 able to surround the N-type electrode in a subsequent bonding process, while preventing both the material of the first bonding layer 2081 and the material of the second bonding layer 2082 from overflowing and short-circuiting.

In a specific embodiment, the thickness of the first bonding layer 2081 is 400 nm˜800 nm, and the thickness of the second bonding layer 2082 is 400 nm˜800 nm.

Referring to FIG. 9, while supporting the chip body by the isolation layer 207, bonding the P-type electrode 304 with the first bonding layer 2081 and simultaneously bonding the N-type electrode 305 with the second bonding layer 2082, wherein the P-type electrode 304 is embedded into the first bonding layer 2081 and the N-type electrode 305 is embedded into the second bonding layer 2082.

In a process of bonding the P-type electrode 304 with the first bonding layer 2081 and simultaneously bonding the N-type electrode 305 with the second bonding layer 2082, a portion of the P-type semiconductor layer 303 around the P-type electrode 304 is supported by the isolation layer 207.

In a process of bonding the P-type electrode 304 with the first bonding layer 2081 and simultaneously bonding the N-type electrode 305 with the second bonding layer 2082, a binding equipment that is used has an error within feature alignment accuracy; the width of the first opening 2071 is greater than or equal to a sum of the width of the P-type electrode 304 and 2 times of the error within feature alignment accuracy, and the width of the second opening 2072 is greater than or equal to a sum of the width of the N-type electrode 305 and 2 times of the error within feature alignment accuracy. In an embodiment, the feature alignment accuracy is 0.5 μm˜2 μm.

When a material of the first bonding layer 2081 and the second bonding layer 2082 is solder, the P-type electrode 304 is bonded to the first bonding layer 2081 by reflow-soldering, and the N-type electrode 305 is bonded to the second bonding layer 2082 by reflow-soldering.

When a material of the first bonding layer 2081 and the second bonding layer 2082 is conductive adhesive, the P-type electrode 304 is pressed into the first bonding layer 2081 to form interconnection between the P-type electrode 304 and conductive particles in the first bonding layer 2081, and the N-type electrode 305 is pressed into the second bonding layer 2082 to form interconnection between the N-type electrode 305 and conductive particles in the second bonding layer 2082.

The first opening 2071 allows the P-type electrode 304 to enter, and the second opening 2072 allows the N-type electrode 305 to enter, while the isolation layer 207 supports the P-type semiconductor layer 303 at a position around the P-type electrode 304. This not only adds a self-alignment function, but also ensures flatness of top surfaces of all the Micro-LED chips on a side away from the second substrate to a certain degree, so that the consistency of light-outputting angles of the Micro-LED chips is enhanced, and an effective light-emitting area of the Micro-LED chips is increased.

Referring to FIG. 10, the Micro-LED chips are peeled off from the first substrate 300.

In a specific embodiment, adopting a manner of ultraviolet light irradiation to peel off the first substrate 300 from the Micro-LED chips.

### Embodiment 2

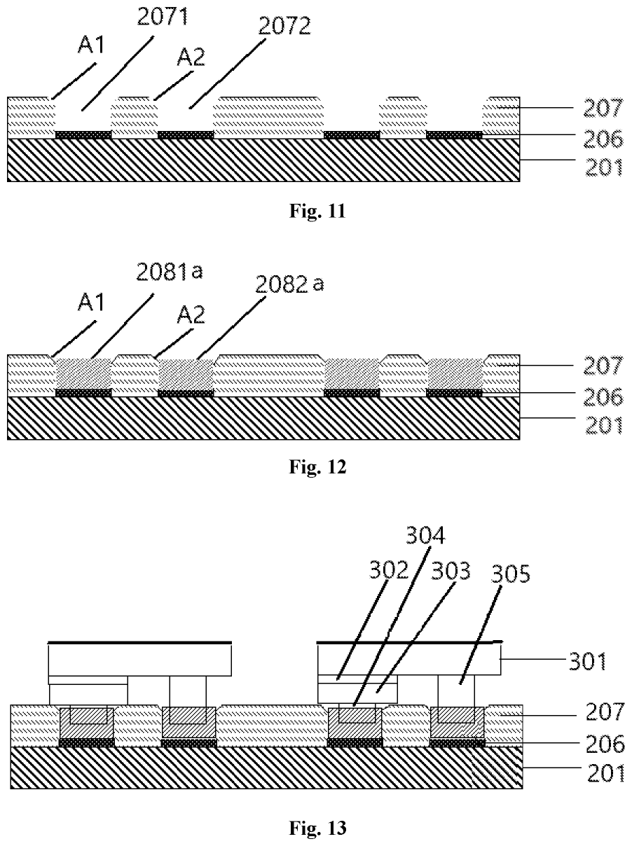

Referring to FIG. 11 which is a schematic diagram based on FIG. 7, wherein a first slope surface A1 is formed at a junction between a side wall of the first opening 2071 and a top surface of the isolation layer 207 around the first opening 2071; a second slope surface A2 is formed at a junction between a side wall of the second opening 2072 and a top surface of the isolation layer 207 around the second opening 2072.

In an embodiment, a first included angle is formed between the first slope surface A1 and the top surface of the isolation layer 207 connected to the first slope surface A1, and tan (180°−θ₁)>μ₁, wherein θ₁ is the first included angle, and μ₁ is a friction coefficient of the first slope surface.

In an embodiment, a second included angle is formed between the second slope surface A2 and the top surface of the isolation layer 207 connected to the second slope surface A2, and tan (180°−θ₂)22 μ₂, wherein θ₂ is the second included angle, and μ₂ is a friction coefficient of the second slope surface.

The aforesaid arrangements of the first included angle and the second included angle have advantages that the P-type electrode 304 of a Micro-LED chip can automatically enter the first opening and the N-type electrode 305 of the Micro-LED chip can automatically enter the second opening, thereby reducing yield loss to a certain degree.

Referring to FIG. 12, after the first slope surface A1 is formed, forming a first bonding layer 2081a in the first opening 2071, and after the second slope surface A2 is formed, forming a second bonding layer 2082a in the second opening 2072.

Referring to FIG. 13, while supporting the chip body by the isolation layer 207, bonding the P-type electrode 304 with the first bonding layer 2081a and simultaneously bonding the N-type electrode 305 with the second bonding layer 2082a, wherein the P-type electrode 304 is embedded into the first bonding layer 2081a and the N-type electrode 305 is embedded into the second bonding layer 2082a; after that, the Micro-LED chips are peeled off from the first substrate 300.

### Embodiment 3

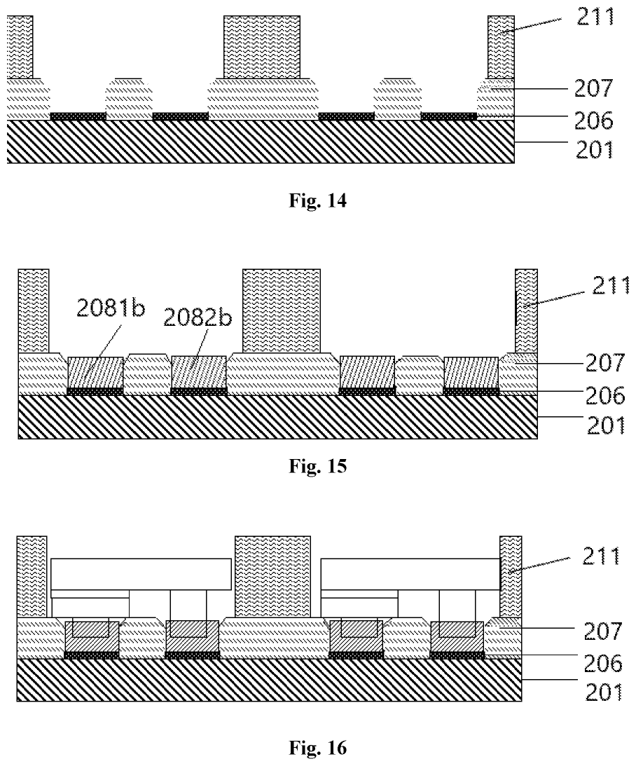

Referring to FIG. 14 which is a schematic diagram based on FIG. 7, wherein a barrier layer 211 is formed on the isolation layer 207 around the opening groups, the barrier layer 211 has third openings, and each of the third openings has a width greater than that of each of the Micro-LED chips.

In an embodiment, the material of the barrier layer 211 is light-shielding resin which is a type of resin that has a light-shielding effect, but the material of the barrier layer 211 is not limited to this type of material, and a width of a third opening should be slightly larger than a width dimension of the Micro-LED chip, so as to ensure that the Micro-LED chip can smoothly fall into the third opening. One third opening corresponds to one Micro-LED chip.

A function of the barrier layer 211 includes limiting a position of the Micro-LED chip, wherein one Micro-LED chip falls into one third opening.

In an embodiment, the barrier layer 211 is a light-shielding barrier layer. The barrier layer 211 is used to block crosstalk between lights emitted by adjacent Micro-LED chips. The material of the light-shielding barrier layer may be, for example, light-shielding resin.

The barrier layer 211 may also be selected to be made of a non-light-shielding material.

In an embodiment, the width of the third opening is greater than the width of the Micro-LED chip and less than or equal to 1.5 times the width of the Micro-LED chip.

In an embodiment, the barrier layer 211 is a light-shielding barrier layer, after the P-type electrode is bonded to the first bonding layer and the N-type electrode is bonded to the second bonding layer, a height of the top surface of the barrier layer 211 on a side away from the second substrate is greater than a height of the top surface of each of the Micro-LED chips on a side away from the second substrate. The advantage of this arrangement is that the crosstalk between the lights emitted by adjacent Micro-LED chips can be better prevented.

It should be noted that, in other embodiments, after the P-type electrode is bonded to the first bonding layer and the N-type electrode is bonded to the second bonding layer, the height of the top surface of the barrier layer 211 on the side away from the second substrate may also be less than or equal to the height of the top surface of each of the Micro-LED chips on the side away from the second substrate.

In this embodiment, the method further comprises forming a first slope surface at a junction between a sidewall of the first opening 2071 and a top surface of the isolation layer 207 around the first opening 2071, and forming a second slope surface at a junction between a sidewall of the second opening 2072 and a top surface of the isolation layer 207 around the second opening 2072. After forming the first slope surface and the second slope surface, the barrier layer 211 is formed. Description of the first slope surface and the second slope surface can refer to the aforesaid embodiments, thus is not described in detail again.

It should be noted that, in other embodiments, in the case of the barrier layer 211 is formed, the first slope surface and the second slope surface may not be provided.

Referring to FIG. 15, a first bonding layer 2081b is formed in the first opening 2071, and a second bonding layer 2082b is formed in the second opening 2072.

In this embodiment, after forming the barrier layer 211, the first bond layer 2081b and the second bond layer 2082b are formed. In other embodiments, the barrier layer 211 may also be formed after forming the first bond layer 2081b and the second bond layer 2082b.

Referring to FIG. 16, while supporting the chip body by the isolation layer 207, the P-type electrode 304 is bonded to the first bonding layer 2081b and simultaneously the N-type electrode 305 is bonded to the second bonding layer 2082b, wherein the P-type electrode 304 is embedded into the first bonding layer 2081b, and the N-type electrode 305 is embedded into the second bonding layer 2082b.

### Embodiment 4

This embodiment provides a display panel, referring to FIG. 10, including:

a plurality of Micro-LED chips that are spaced apart from each other, wherein each of the plurality of Micro-LED chips includes a chip body, with a P-type electrode 304 and a N-type electrode 305 arranged on part of a surface on a side of the chip body;

a second substrate 201, wherein a surface on a side of the second substrate 201 has a plurality of conductive layer parts 206;

an isolation layer 207, positioned on the side of the second substrate 201, wherein the isolation layer 207 has a plurality of opening groups, each of the opening groups comprises a first opening and a second opening that are spaced apart from each other, the first opening and the second opening are respectively positioned over one of the conductive layer parts 206, a width of the first opening is greater than a width of the P-type electrode 304, and a width of the second opening is greater than a width of the N-type electrode 305;

a first bonding layer, positioned in the first opening;

a second bonding layer, positioned in the second opening;

wherein the P-type electrode 304 is embedded in the first bonding layer, and the N-type electrode 305 is embedded in the second bonding layer; the chip body touches part of a top surface of the isolation layer 207.

The chip body comprises: a N-type semiconductor layer 301; an active layer 302, positioned on part of a surface on a side of the N-type semiconductor layer 301; a P-type semiconductor layer 303, positioned on a surface on a side, away from the N-type semiconductor layer 301, of the active layer 302; the P-type electrode 304 is positioned on part of a surface on a side, away from the active layer 302, of the P-type semiconductor layer 303; the N-type electrode 305 is positioned on part of the surface on the side of the N-type semiconductor layer 301 and arranged laterally beside the active layer 302, the P-type semiconductor layer 303 and the P-type electrode 304; a portion of the P-type semiconductor layer 303 around the P-type electrode 304 touches the top surface of the isolation layer 207 around the first opening.

In an embodiment, the width of the first opening is greater than or equal to a sum of the width of the P-type electrode 304 and 2 times of an error within feature alignment accuracy, and the width of the second opening is greater than or equal to a sum of the width of the N-type electrode 305 and 2 times of the error within feature alignment accuracy, wherein the error within the feature alignment accuracy is 0.5 μm˜2 μm.

In an embodiment, a thickness of the first bonding layer is greater than or equal to 80% of a depth of the first opening and less than or equal to the depth of the first opening, and a thickness of the second bonding layer is greater than or equal to 80% of a depth of the second opening and less than or equal to the depth of the second opening.

In an embodiment, a thickness of the isolation layer 207 is less than or equal to 50% of a thickness difference between the N-type electrode and the P-type electrode.

In an embodiment, the thickness of the isolation layer 207 is 500 nm˜1000 nm.

A material of the first bonding layer and the second bonding layer is solder; or a material of the first bonding layer and the second bonding layer is conductive adhesive.

### Embodiment 5

Differences between this embodiment and the Embodiment 4 are as follows: Referring to FIG. 13, a first slope surface A1 (referring to FIG. 12) is provided between a sidewall of the first opening and the top surface of the isolation layer 207 around the first opening; a second slope surface A2 (referring to FIG. 12) is provided between a sidewall of the second opening and the top surface of the isolation layer 207 around the second opening.

In an embodiment, a first included angle is formed between the first slope surface and the top surface of the isolation layer connected to the first slope surface, and tan (180°−θ₁)>μ₁, wherein θ₁ is the first included angle, and μ₁ is a friction coefficient of the first slope surface.

In an embodiment, a second included angle is formed between the second slope surface and the top surface of the isolation layer connected to the second slope surface, and tan (180°−θ₂)>μ₂, wherein θ₂ is the second included angle, and μ₂ is a friction coefficient of the second slope surface.

### Embodiment 6

Differences between this embodiment and the Embodiment 5 are as follows: Referring to FIG. 16, the display panel further includes: a barrier layer 211, positioned upon the isolation layer 207 around the opening groups, wherein the barrier layer 211 has third openings, and a width of each of the third openings is greater than a width of each of the Micro-LED chips.

In an embodiment, the width of each of the third openings is less than or equal to 1.5 times of the width of each of the Micro-LED chips.

In an embodiment, the barrier layer 211 is a light-shielding barrier layer. A material of the light-shielding barrier layer is light-shielding resin. In other embodiments, a material of the barrier layer 211 may also be a non-light-shielding material.

In an embodiment, the barrier layer 211 is a light-shielding barrier layer wherein a height of a top surface on a side, away from the second substrate, of the barrier layer is greater than a height of a top surface on a side, away from the second substrate, of each of the Micro-LED chips.

In another embodiment, a height of a top surface on a side, away from the second substrate, of the barrier layer may also be less than or equal to a height of a top surface on a side, away from the second substrate, of each of the Micro-LED chips.

Those contents of this embodiment that are identical to those of Embodiment 5 are not further described in detail again.

### Embodiment 7

Differences between this embodiment and the Embodiment 4 are as follows: The display panel further includes: a barrier layer, positioned upon the isolation layer around the opening groups, wherein the barrier layer has third openings, and a width of each of the third openings is greater than a width of each of the Micro-LED chips. In an embodiment, the width of each of the third openings is less than or equal to 1.5 times of the width of each of the Micro-LED chips.

In an embodiment, the barrier layer 211 is a light-shielding barrier layer. A material of the light-shielding barrier layer is light-shielding resin. In other embodiments, a material of the barrier layer 211 may also be a non-light-shielding material.

In an embodiment, the barrier layer 211 is a light-shielding barrier layer wherein a height of a top surface on a side, away from the second substrate, of the barrier layer is greater than a height of a top surface on a side, away from the second substrate, of each of the Micro-LED chips. In another embodiment, a height of a top surface on a side, away from the second substrate, of the barrier layer may also be less than or equal to a height of a top surface on a side, away from the second substrate, of each of the Micro-LED chips.

Those contents of this embodiment that are identical to those of Embodiment 4 are not further described in details again.

Apparently, the aforesaid embodiments are merely examples for providing clear description and are not intended to limit the implementing ways thereof. Other variations or modifications in different forms may be made on the basis of the above description for a person skilled in the art. It is unnecessary and impossible to exhaustively list all implementing ways herein. Obvious variations or modifications derived therefrom are still within the protection scope of the present invention application.

1. A manufacturing method for a display panel, comprising:
providing a first substrate, wherein a side of the first substrate is provided with a plurality of Micro-LED chips that are spaced apart from each other, wherein each of the Micro-LED chips comprises: a chip body; a P-type electrode and a N-type electrode, which are arranged on part of a surface on a side of the chip body;
providing a second substrate, wherein a surface on a side of the second substrate has a plurality of conductive layer parts;
forming an isolation layer on the second substrate, wherein the isolation layer has a plurality of opening groups, each of the opening groups comprises a first opening and a second opening that are spaced apart from each other, wherein the first opening and the second opening respectively expose a surface of one of the conductive layer parts, and a width of the first opening is greater than a width of the P-type electrode, and a width of the second opening is greater than a width of the N-type electrode;
forming a first bonding layer in the first opening and forming a second bonding layer in the second opening;
while supporting the chip body by the isolation layer, bonding the P-type electrode with the first bonding layer and simultaneously bonding the N-type electrode with the second bonding layer, wherein the P-type electrode is embedded into the first bonding layer and the N-type electrode is embedded into the second bonding layer.

2. The manufacturing method for a display panel according to claim 1, wherein, the chip body comprises: a N-type semiconductor layer; an active layer, positioned on part of a surface on a side of the N-type semiconductor layer; a P-type semiconductor layer, positioned on a surface on a side, away from the N-type semiconductor layer, of the active layer;
the P-type electrode is positioned on part of a surface on a side, away from the active layer, of the P-type semiconductor layer; the N-type electrode is positioned on part of the surface on the side of the N-type semiconductor and arranged laterally beside the active layer, the P-type semiconductor layer and the P-type electrode;
in a process of bonding the P-type electrode with the first bonding layer and simultaneously bonding the N-type electrode with the second bonding layer, a portion of the P-type semiconductor layer around the P-type electrode is supported by the isolation layer.

3. The manufacturing method for a display panel according to claim 1, further comprising: before the step of forming the first bonding layer in the first opening, forming a first slope surface at a junction between a sidewall of the first opening and a top surface of the isolation layer around the first opening; before the step of forming the second bonding layer in the second opening, forming a second slope surface at a junction between a sidewall of the second opening and a top surface of the isolation layer around the second opening.

4. The manufacturing method for a display panel according to claim 3, wherein, a first included angle is formed between the first slope surface and the top surface of the isolation layer connected to the first slope surface; wherein tan (180°−θ1)>μ1, wherein θ1 is the first included angle, and μ1 is a friction coefficient of the first slope surface.

5. The manufacturing method for a display panel according to claim 3, wherein, a second included angle is formed between the second slope surface and the top surface of the isolation layer connected to the second slope surface; wherein tan (180°−θ2)>μ2, wherein θ2 is the second included angle, and μ2 is a friction coefficient of the second slope surface.

6. The manufacturing method for a display panel according to claim 1, further comprising: before the step of bonding the P-type electrode with the first bonding layer and simultaneously bonding the N-type electrode with the second bonding layer, forming a barrier layer upon the isolation layer around the opening groups, wherein the barrier layer has third openings, and a width of each of the third openings is greater than a width of each of the Micro-LED chips.

7. The manufacturing method for a display panel according to claim 6, wherein, the width of each of the third openings is less than or equal to 1.5 times of the width of each of the Micro-LED chips.

8-10. (canceled)

11. The manufacturing method for a display panel according to claim 1, wherein, in a process of bonding the P-type electrode with the first bonding layer and simultaneously bonding the N-type electrode with the second bonding layer, a binding equipment that is used has an error within feature alignment accuracy;
the width of the first opening is greater than or equal to a sum of the width of the P-type electrode and 2 times of the error within feature alignment accuracy, and the width of the second opening is greater than or equal to a sum of the width of the N-type electrode and 2 times of the error within feature alignment accuracy.

12. The manufacturing method for a display panel according to claim 1, wherein, in the step of forming the first bonding layer in the first opening, a thickness of the formed first bonding layer is greater than or equal to 80% of a depth of the first opening and less than or equal to the depth of the first opening, and in the step of forming the second bonding layer in the second opening, a thickness of the formed second bonding layer is greater than or equal to 80% of a depth of the second opening and less than or equal to the depth of the second opening.

13. The manufacturing method for a display panel according to claim 1, wherein, a thickness of the isolation layer is less than or equal to 50% of a thickness difference between the N-type electrode and the P-type electrode.

14-15. (canceled)

16. A display panel, comprising:
a first substrate, wherein a side of the first substrate is provided with a plurality of Micro-LED chips that are spaced apart from each other, and each of the Micro-LED chips comprises: a chip body; a P-type electrode and a N-type electrode, which are arranged on part of a surface on a side of the chip body;
a second substrate, wherein a surface on a side of the second substrate has a plurality of conductive layer parts;
an isolation layer, positioned on the side of the second substrate, wherein the isolation layer has a plurality of opening groups, each of the opening groups comprises a first opening and a second opening that are spaced apart from each other, the first opening and the second opening are respectively positioned over one of the conductive layer parts, a width of the first opening is smaller than a width of the P-type electrode, and a width of the second opening is smaller than a width of the N-type electrode;
a first bonding layer, positioned in the first opening;
a second bonding layer, positioned in the second opening;
wherein the P-type electrode is embedded in the first bonding layer, and the N-type electrode is embedded in the second bonding layer; the chip body touches part of a top surface of the isolation layer.

17. The display panel according to claim 16, wherein, the chip body comprises: a N-type semiconductor layer; an active layer, positioned on part of a surface on a side of the N-type semiconductor layer; a P-type semiconductor layer, positioned on a surface on a side, away from the N-type semiconductor layer, of the active layer;
the P-type electrode is positioned on part of a surface on a side, away from the active layer, of the P-type semiconductor layer; the N-type electrode is positioned on part of the surface on the side of the N-type semiconductor and arranged laterally beside the active layer, the P-type semiconductor layer and the P-type electrode; a portion of the P-type semiconductor layer around the P-type electrode touches the top surface of the isolation layer around the first opening.

18. The display panel according to claim 16, wherein, a first slope surface is provided between a sidewall of the first opening and the top surface of the isolation layer around the first opening; a second slope surface is provided between a sidewall of the second opening and the top surface of the isolation layer around the second opening.

19. The display panel according to claim 18, wherein, a first included angle is formed between the first slope surface and the top surface of the isolation layer connected to the first slope surface; wherein tan (180°−θ1)>μ1, wherein θ1 is the first included angle, and μ1 is a friction coefficient of the first slope surface.

20. The display panel according to claim 18, wherein, a second included angle is formed between the second slope surface and the top surface of the isolation layer connected to the second slope surface; wherein tan (180°−θ2)>μ2, wherein θ2 is the second included angle, and μ2 is a friction coefficient of the second slope surface.

21. The display panel according to claim 16, further comprising: a barrier layer, positioned upon the isolation layer around the opening groups, wherein the barrier layer has third openings, and a width of each of the third openings is greater than a width of each of the Micro-LED chips.

22. The display panel according to claim 21, wherein, the width of each of the third openings is less than or equal to 1.5 times of the width of each of the Micro-LED chips.

23-25. (canceled)

26. The display panel according to claim 16, wherein, the width of the first opening is greater than or equal to a sum of the width of the P-type electrode and 2 times of an error within feature alignment accuracy, and the width of the second opening is greater than or equal to a sum of the width of the N-type electrode and 2 times of the error within feature alignment accuracy, wherein the error within the feature alignment accuracy is 0.5 μm˜2 μm.

27. The display panel according to claim 16, wherein, a thickness of the first bonding layer is greater than or equal to 80% of a depth of the first opening and less than or equal to the depth of the first opening, and a thickness of the second bonding layer is greater than or equal to 80% of a depth of the second opening and less than or equal to the depth of the second opening.

28. The display panel according to claim 16, wherein, a thickness of the isolation layer is less than or equal to 50% of a thickness difference between the N-type electrode and the P-type electrode.

29-30. (canceled)
